(19) United States
(12) Patent Application Publication
(10) Pub. No.: US 2015/0321222 A1
(43) Pub. Date: Nov. 12, 2015

(54) PIEZOELECTRIC ELEMENT AND PIEZOELECTRIC VIBRATION MODULE HAVING THE SAME

(71) Applicant: SAMSUNG ELECTRO-MECHANICS CO., LTD., Suwon (KR)

(72) Inventors: Boum-Seock KIM, Suwon (KR); Kyung-Lock KIM, Seongnam (KR); Seung-Ho LEE, Suwon (KR); Jung-Wook SEO, Hwaseong (KR); Hui-Sun PARK, Seoul (KR)

(73) Assignee: SAMSUNG ELECTRO-MECHANICS CO., LTD., Suwon (KR)

(21) Appl. No.: 14/687,324

(22) Filed: Apr. 15, 2015

(30) Foreign Application Priority Data
May 7, 2014 (KR) 10-2014-0054394
Aug. 27, 2014 (KR) 10-2014-0112503

(51) Int. Cl. B06B 1/06; H01L 41/047; H01L 41/083

(52) U.S. Cl. CPC B06B 1/0603; H01L 41/0838; H01L 41/0474

(57) ABSTRACT

A piezoelectric element and piezoelectric vibration module include a piezoelectric material having a plurality of piezoelectric layers laminated thereon and internal electrodes laminated alternately with the piezoelectric layers, respectively. Among the plurality of piezoelectric layers, a magnitude of applied electric field on a piezoelectric layer located at one end is smaller than a magnitude of applied electric field on a piezoelectric layer located at the other end.

### CROSS-REFERENCE TO RELATED APPLICATIONS

This application claims the foreign priority benefit under 35 U.S.C. §119 of Korean Patent Application No. 10-2014-0054394 filed with the Korean Intellectual Property Office on May 7, 2014, and Korean Patent Application No. 10-2014-0112503, filed with the Korean Intellectual Property Office on Aug. 27, 2014, the disclosures of which are incorporated herein by reference in their entirety.

### BACKGROUND

1. Field

The following description relates to a piezoelectric element and a piezoelectric vibration module having the piezoelectric element.

2. Description of Related Art

Touch panels, touch keyboards, and the like can be installed on electronic devices to provide vibrations to user's fingertips when letters or drawings are input.

Such a function may be realized through a structure in which vibrations are transferred to the user by having the vibrations provided to a touch panel by a vibration generator, such as a piezoelectric actuator.

Piezoelectric ceramics can be used for piezoelectric actuators. However, when the piezoelectric ceramics vibrate according to the piezoelectric properties thereof, the piezoelectric ceramics may be cracked. If the occurrence rate of cracks is high, the reliability of the piezoelectric actuators is lowered.

Japan Patent Publication No. 2002-299706 (LAMINATED PIEZOELECTRIC ACTUATOR; laid open on Oct. 11, 2002) describes a laminated piezoelectric actuator having a plurality of active layers composed of ceramic laminates.

### SUMMARY

Additional aspects and/or advantages will be set forth in part in the description which follows and, in part, will be apparent from the description, or may be learned by practice of the invention.

The present disclosure provides a piezoelectric element and a piezoelectric vibration module having the piezoelectric element that can reduce the occurrence rate of cracks in the piezoelectric element.

A piezoelectric element may have a magnitude of applied electric field on a piezoelectric layer located at one end smaller than a magnitude of applied electric field on a piezoelectric layer located at the other end. The piezoelectric element may include a piezoelectric material having a plurality of piezoelectric layers laminated thereon and internal electrodes laminated alternately with the piezoelectric layers, respectively.

The piezoelectric layer located at the one end may be thicker than the piezoelectric layer located at the other end. The piezoelectric layer located at the one end may be thickest among the plurality of the piezoelectric layers, and the piezoelectric layer located at the other end may be thinnest among the plurality of piezoelectric layers. Moreover, thicknesses of the piezoelectric layers may become smaller from the one end toward the other end. A ratio of thickness between the piezoelectric layer located at the one end and the piezoelectric layer located at the other end may be greater than or equal to 0.6 and smaller than or equal to 0.8.

The piezoelectric material may be constituted with a plurality of grouped layers, which are each constituted with two or more of the piezoelectric layers that have a same thickness and are consecutively laminated, and, among the plurality of grouped layers, a grouped layer located at the one end may be thicker than a grouped layer located at the other end.

The piezoelectric layers may be made of a material including a PNN-PZT ceramic. The piezoelectric element may further include a via and terminals. Moreover, the piezoelectric element may further include a non-piezoelectric layer being laminated on at least one of the piezoelectric layer located at the one end and the piezoelectric layer located at the other end.

A piezoelectric vibration module may include a piezoelectric element in which a magnitude of applied electric field on a piezoelectric layer located at one end is smaller than a magnitude of applied electric field on a piezoelectric layer located at the other end.

The piezoelectric vibration module may include the piezoelectric element and a vibrating plate. The piezoelectric layer located at the one end may be thicker than the piezoelectric layer located at the other end. The piezoelectric layer located at the one end may be thickest among the plurality of the piezoelectric layers, and the piezoelectric layer located at the other end may be thinnest among the plurality of piezoelectric layers. Moreover, thicknesses of the piezoelectric layers may become smaller from the one end toward the other end. A ratio of thickness between the piezoelectric layer located at the one end and the piezoelectric layer located at the other end may be greater than or equal to 0.6 and smaller than or equal to 0.8.

The piezoelectric vibration module may further include a weight, a case, and a substrate.

An apparatus having a vibration function may include a piezoelectric vibration module configured to provide the vibration, the piezoelectric vibration module including a vibrating plate, and a piezoelectric element coupled to the vibrating plate and configured to deform when an electric field is applied, the piezoelectric element including a first piezoelectric layer, a second piezoelectric layer coupled to the first piezoelectric layer, thinner than the first piezoelectric layer, and closer to the vibrating plate than the first piezoelectric layer, and a plurality of electrodes configured to apply the electric field to the first piezoelectric layer and the second piezoelectric layer.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a perspective view showing a piezoelectric vibration module in accordance with an embodiment of the present disclosure.

FIG. 2 is an exploded view showing the piezoelectric vibration module in accordance with an embodiment of the present disclosure.

FIG. 3 shows a portion of the piezoelectric vibration module in accordance with an embodiment of the present disclosure.

FIG. 4 and FIG. 5 show vibrations of the piezoelectric vibration module in accordance with an embodiment of the present disclosure.

FIG. 6 shows a piezoelectric element in accordance with an embodiment of the present disclosure.

FIG. 7 shows a piezoelectric element in accordance with an embodiment of the present disclosure.

FIG. 8 shows a piezoelectric element in accordance with an embodiment of the present disclosure.

FIG. 9 shows a piezoelectric element in accordance with an embodiment of the present disclosure.

FIG. 10 shows a piezoelectric element in accordance with an embodiment of the present disclosure.

### DETAILED DESCRIPTION

Reference will now be made in detail to embodiments, examples of which are illustrated in the accompanying drawings, wherein like reference numerals refer to the like elements throughout. The embodiments are described below to explain the present disclosure by referring to the figures.

Hereinafter, embodiments of a piezoelectric element and a piezoelectric vibration module having the same in accordance with the present disclosure will be described in detail with reference to the accompanying drawings. In describing embodiments of the present disclosure with reference to the accompanying drawings, any identical or corresponding elements will be assigned with same reference numerals, and their redundant description will not be provided.

Terms such as “first” and “second” can be used in describing various elements, but the above elements shall not be restricted to the above terms. The above terms are used only to distinguish one element from the other.

When one element is described as being “coupled” or “connected” to another element, it shall be construed as not only being in physical contact with the other element but also as possibly having a third element interposed therebetween and each of the one element and the other element being in contact with the third element.

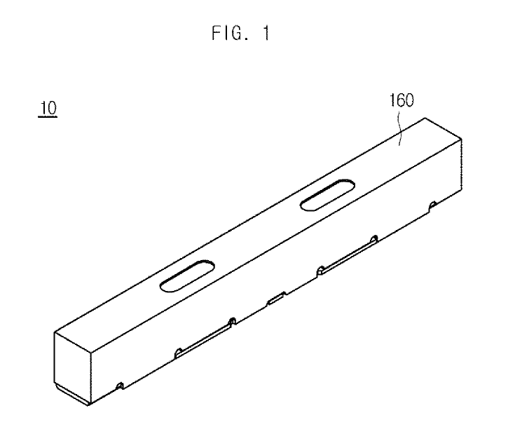

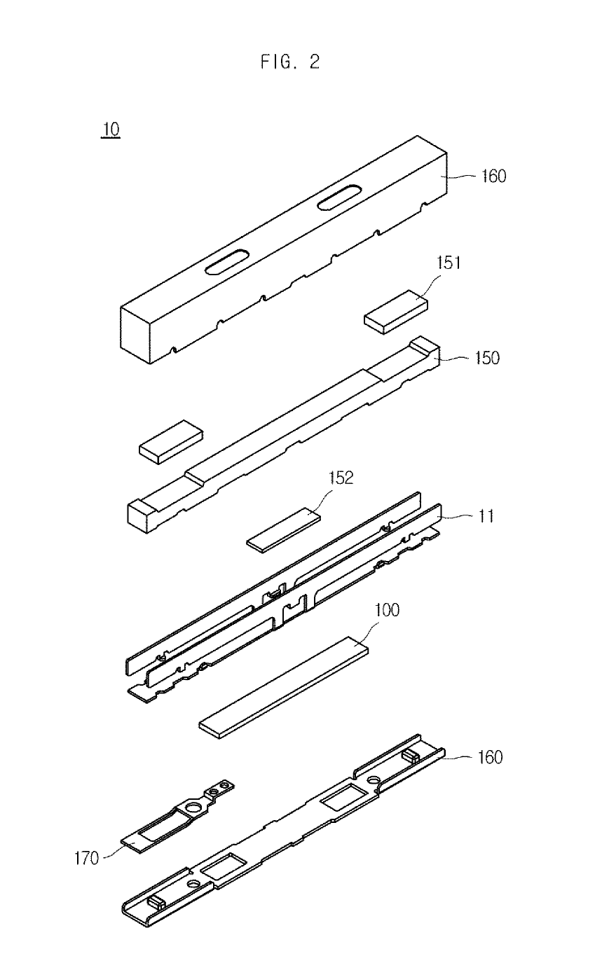

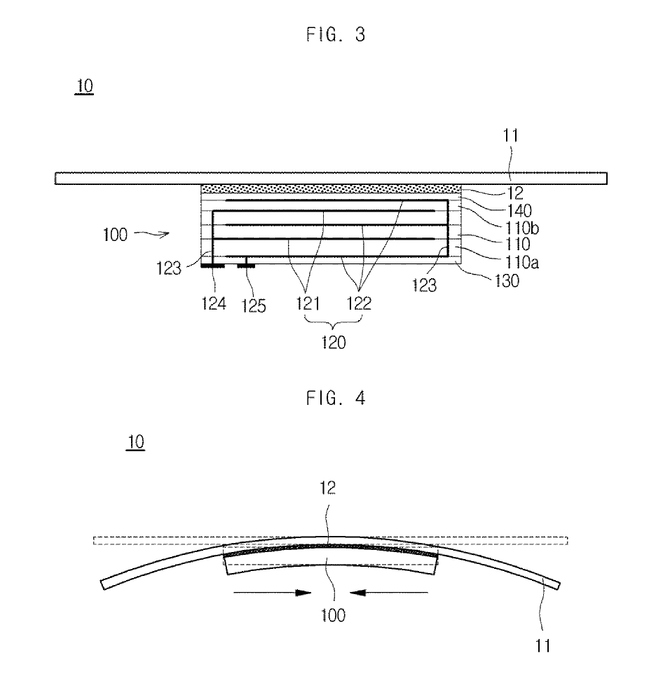

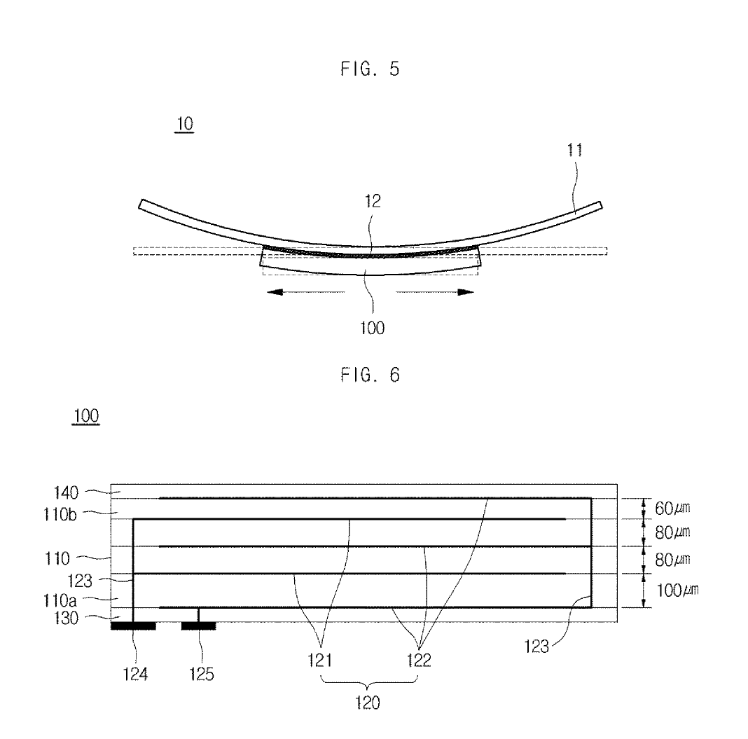

FIG. 1 is a perspective view showing a piezoelectric vibration module in accordance with an embodiment of the present disclosure. FIG. 2 is an exploded view showing the piezoelectric vibration module in accordance with an embodiment of the present disclosure. FIG. 3 shows a portion of the piezoelectric vibration module in accordance with an embodiment of the present disclosure. FIG. 4 and FIG. 5 show vibrations of the piezoelectric vibration module in accordance with an embodiment of the present disclosure. FIG. 6 shows a piezoelectric element in accordance with an embodiment of the present disclosure.

Referring to FIG. 1 to FIG. 5, a piezoelectric vibration module 10 may include a vibrating plate 11 and a piezoelectric element 100. Moreover, the piezoelectric element 100 may include a piezoelectric material formed by laminating a plurality of piezoelectric layers 110 and internal electrodes 120.

The vibrating plate 11, which is a plate designed to vibrate according to a movement of the piezoelectric element 100, performs a function of transferring vibrations to a touch panel, an image display unit, HPP or the like, and the transferred vibrations are realized in a haptic technology.

The vibrating plate 11 may be made of steel, including stainless steel (SUS), for example. The vibrating plate 11 may be made of invar, which is a material having a similar coefficient of thermal expansion to that of the piezoelectric element 100. However, the disclosure is not limited thereto, and the vibrating plate may be composed of any suitable material.

In the case where the vibrating plate 11 is made of invar, it may be possible to prevent a bending phenomenon that can result from hardening of an adhesive material 12, when the vibrating plate 11 and the piezoelectric element 100 are coupled by the adhesive material 12.

The vibrating plate 11 may include a lower-portion plate and upper-portion plates. The lower-portion plate is where the piezoelectric element 100 is coupled, and the upper-portion plates, which are coupled to either side of the lower-portion plate, are where a weight 150, which will be described later, is coupled. The lower-portion plate and upper-portion plates may be formed integrally as a single part or may be affixed to one another by use of various coupling methods. Illustrated in FIG. 3 to FIG. 5 is the lower-portion plate of the vibrating plate 11.

The piezoelectric element 100 is an element that has a property of contracting and expanding when voltage is supplied. When voltage is supplied to the piezoelectric element 100, an electric field is formed between two poles (+, −) in the piezoelectric layer 110, and the internal structure of the piezoelectric layer 110 is changed by a dipole occurring within the piezoelectric layer 110, allowing the piezoelectric layer 110 to contract and expand.

As illustrated in FIG. 3, the piezoelectric element 100 may be coupled to one surface of the vibrating plate 11 to cause the vibrating plate 110 to vibrate. That is, the piezoelectric property of the piezoelectric element 100 may induce vibrations on the vibrating plate 11.

As illustrated in FIG. 4 and FIG. 5, the piezoelectric element 100 may be contracted and expanded in a length-wise direction according to the supply of voltage, resulting in up-down, or cross-wise, vibrations of the vibrating plate 11 coupled to the piezoelectric element 100 by a deforming of the piezoelectric element 100 and the vibrating plate 11.

The piezoelectric element 100 may be readily adhered to the vibrating plate 11 by the adhesive material 12. Moreover, the adhesive material 12 may insulate the piezoelectric element 100 from the vibrating plate 11.

The piezoelectric layer 110, which is a layer having piezoelectric properties, may be made of a material including a PNN-PZT (lead zirconate titanate) ceramic, for example. In such a case, the following composition may be a main component of the piezoelectric layer 110.

x[Pb{Zr_{y}Ti_{(1-y)}}O₃]-(1−x)[Pb(Ni_{z}Nb_{(1-z)})O₃]

Here, x, y, and z may be constants 0.8, 0.44 and ⅓, respectively.

Moreover, the material for the piezoelectric layer 110 may further include a secondary component that is used for a sintering aid. The sintering aid used as the secondary component may include at least one of NiO, CuO, ZnO, and PbO, for example.

The piezoelectric material is constituted with a plurality of piezoelectric layers 110, and the piezoelectric element 100 having the plurality of piezoelectric layers 110 may provide an electric field sufficient for driving the piezoelectric element 100. In other words, the piezoelectric element 100 having the plurality of piezoelectric layers 110 has an advantage of being able to realize a greater piezoelectric property for a given voltage.

Among the plurality of piezoelectric layers 110 of the piezoelectric material, the magnitude of applied electric field of a piezoelectric layer 110a located at one end is smaller than that of a piezoelectric layer 110b located at the other end.

Here, the “one end” refers to a layer that is farthest in one direction of the plurality of piezoelectric layers 110, and the “other end” refers to a layer that is farthest in the other direction of the plurality of piezoelectric layers 110. Moreover, in the case where the piezoelectric element 100 is coupled to the vibrating plate 11, the “one end” refers to the layer that is farthest from the vibrating plate 11, and the “other end” refers to the closest layer to the vibrating plate 11.

In the case of a piezoelectric element including a plurality of piezoelectric layers having the same thicknesses, stress exerted to a piezoelectric layer that is farther away from a vibrating plate is observed to be greater than stress exerted to a piezoelectric layer that is closer to the vibrating plate, when the piezoelectric element and the vibrating plate vibrate. This is because a point where stress is zero is located closer to the vibrating plate from a center of the piezoelectric element.

In the present disclosure, the magnitude of applied electric field of the piezoelectric layer 110a that is located away from the vibrating plate 11 may be smaller than that of the piezoelectric layer 110b that is closer to the vibrating plate 11. In such a case, when the piezoelectric element 100 is contracted and expanded, the stress exerted to the piezoelectric layer 110a that is farthest from the vibrating plate 11 is relatively smaller than the stress exerted to the piezoelectric layer 110a that is closest to the vibrating plate 11.

Therefore, when the piezoelectric element 100 and the vibrating plate 11 are coupled with each other and vibrate, the stress on the piezoelectric layer 110a farthest from the vibrating plate 11 and the stress on the piezoelectric layer 110b closest to the vibrating plate 11 may be balanced. In other words, when the piezoelectric element 100 and the vibrating plate 11 vibrate, a point where stress is zero may become closer to a center of the piezoelectric element 100.

When the piezoelectric element 100 and the vibrating plate 11 vibrate, the point where stress becomes zero may be located at the center of the piezoelectric element 100, in which case the stress on the piezoelectric layer 100a located on the one end and the piezoelectric layer 110b located on the other end may be identical, or substantially identical, to each other.

A crack may be readily formed at a portion where the stress on the piezoelectric element 100 is excessively large. That is, as the piezoelectric layer 110 of the piezoelectric element 100 may be formed with a plurality of grains, the crack may occur along boundaries of the plurality of grains. In such a case, the crack that occurs at a specific portion of the piezoelectric layer 110 may be spread throughout the piezoelectric element 100.

By allowing the stresses on the piezoelectric layers 110 of the piezoelectric element 100 to be balanced, as in the present disclosure, the occurrence of crack may be reduced.

For the balance of the stresses on the piezoelectric layers 110, the piezoelectric layer 110a located on the one end, among the plurality of piezoelectric layers 110, may be thicker than the piezoelectric layer 110b that is located on the other end.

In such a case, the piezoelectric layer 110a that is located on the one end may be the thickest among the plurality of piezoelectric layers 110.

In an example, in the case where there are 4 layers of piezoelectric layers 110 and the thickness of the piezoelectric material is 320 μm, the piezoelectric layer 110a located on the one end may have the thickness of 110 μm, and the remaining piezoelectric layers may each have the thickness of 70 μm.

In such a case, if 80V is supplied to each of the piezoelectric layers 110, the magnitude of applied electric field on the piezoelectric layer 110a located on the one end may be approximately 0.7 kV/mm, and the magnitude of applied electric field on each of the remaining piezoelectric layers may be approximately 1.1 kV/mm.

Moreover, the piezoelectric layer 110b located on the other end may have the smallest thickness among the plurality of piezoelectric layers 110.

In an example, as illustrated in FIG. 6, in the case where there are 4 layers of piezoelectric layers 110 and the thickness of the piezoelectric material is 320 μm, the piezoelectric layer 110a located on the one end may have the thickness of 100 μm, and the piezoelectric layer 110b located on the other end may have the thickness of 60 μm, and two piezoelectric layers therebetween may each have the thickness of 80 μm.

In such a case, if 80V is supplied, as in the above example, the magnitude of applied electric field on the piezoelectric layer 110a located on the one end may be approximately 0.8 kV/mm, and the magnitude of applied electric field on the piezoelectric layer 110b located on the other end may be approximately 1.3 kV/mm, and the magnitude of applied electric field on each of the remaining piezoelectric layers may be approximately 1 kV/mm.

The ratio of thickness between the piezoelectric layer 110a located on the one end and the piezoelectric layer 110b located on the other end may be greater than or equal to approximately 0.6 and smaller than or equal to approximately 0.8.

If the ratio of thickness exceeds 0.8, the effect of reducing the occurrence of crack in the piezoelectric element may be insignificant, such that the product reliability may be jeopardized. On the other hand, if the thickness ratio is smaller than 0.6, vibrations may become too weak.

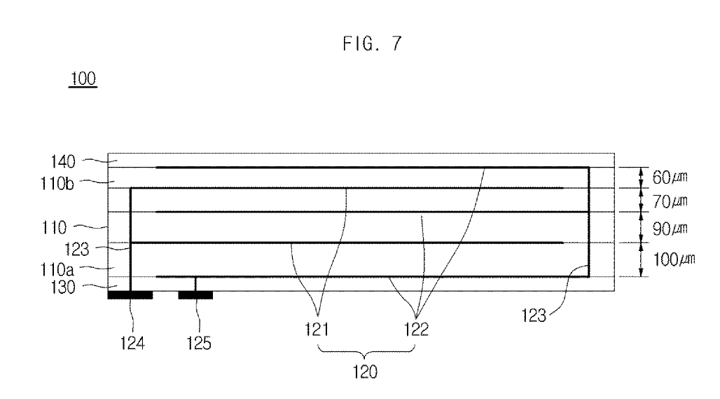

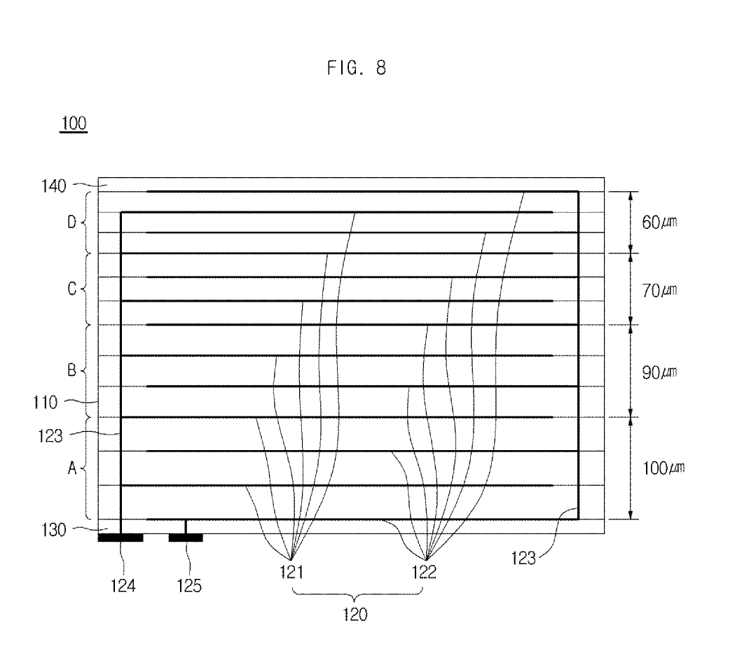

FIG. 7 shows a piezoelectric element in accordance with an embodiment of the present disclosure, and FIG. 8 shows a piezoelectric element in accordance with an embodiment of the present disclosure.

As shown in FIG. 7, thicknesses of a plurality of piezoelectric layers 110 may be increasingly smaller from one end thereof toward the other end thereof. In such a case, when a piezoelectric element 100 is contracted and expanded, a deviation in contraction and expansion between adjacent piezoelectric layers 110 becomes smaller, thereby mitigating a deviation in inter-layer stress.

In an example, in the case where there are 4 layers of piezoelectric layers 110, a piezoelectric layer 110a located on the one end may have the thickness of 100 μm, and a piezoelectric layer 110b located on the other end may have the thickness of 60 μm, and piezoelectric layers therebetween may have the thicknesses of 90 μm and 70 μm, respectively.

In such a case, the magnitude of applied electric field of the piezoelectric layers 110 becomes increasingly greater from the one end to the other end. Specifically, the magnitude of applied electric field is 0.8 kV/mm, 8/9 kV/mm, 1.1 kV/mm and 1.3 kV/mm, from the one end to the other end.

As shown in FIG. 8, a piezoelectric material may be constituted with a plurality of grouped layers A, B, C, D. The grouped layers are each constituted with at least two consecutively-laminated piezoelectric layers having the same thickness. The number of piezoelectric layers belonging to one grouped layer may be 25% of the total number of piezoelectric layers.

In such a case, the thickness of a grouped layer located on one end, among the plurality of grouped layers is greater than the thickness of a grouped layer located on the other end. That is, in terms of thickness, the grouped layers may correspond to the above-described piezoelectric layers.

In an example, in the case where a piezoelectric layer 110 is constituted with 12 layers, three consecutively-laminated layers may form one grouped layer. In such a case, the piezoelectric material may have four grouped layers A, B, C, and D. The thickness of the grouped layer A that is located on the one end may be 100 μm, which is greater than the thickness of 60 μm of the grouped layer D that is located on the other end.

The grouped layer located on the one end may have the greatest thickness among the plurality of grouped layers, and the grouped layer located on the other end may have the smallest thickness among the plurality of grouped layers. Moreover, as shown in FIG. 8, the thickness of the plurality of grouped layers may be increasingly smaller from the one end toward the other end.

The internal electrodes 120 are conductors that form an electric field with the piezoelectric layers 110. The internal electrodes 120 may be each formed alternately with each of the piezoelectric layers 110 and may be formed between the plurality of piezoelectric layers 110 and on an external surface of an end-most piezoelectric layer 110. The electrode formed on the external surface of the end-most piezoelectric layer 110 may be exposed to an outside of the piezoelectric layer 110.

The internal electrodes 120 and the piezoelectric layers 110 may be laminated side by side. Here, being “side by side” refers to the internal electrodes 120 being parallel with the piezoelectric layers 110, respectively.

The internal electrodes 120 may be divided into first electrodes 121 and second electrodes 122. The first electrodes 121 and the second electrodes 122 may have different polarities from each other. For example, in the case where the first electrodes 121 have a positive (+) polarity, the second electrodes 122 may have a negative (−) polarity.

The first electrodes 121 and the second electrodes 122 are alternately formed. As described above, in the case where there are 4 layers of piezoelectric layers 110, the internal electrodes 120 may be constituted with two first electrodes 121 and three second electrodes 122.

The internal electrodes 120 may be formed by having an electrode paste, which includes at least one of silver (Ag) and palladium (Pd), printed and then fired. For instance, the mixing ratio of silver and palladium may be greater than or equal to approximately 7/3 and smaller than or equal to approximately 9.5/0.5 (silver/palladium).

The electrode paste may be printed on one surface or both surfaces of each of the piezoelectric layers 110, and a printed area of the electrode paste may be smaller than an area of one surface of a single piezoelectric layer 110.

Referring to FIG. 7, the piezoelectric element 100 may further include a via, or conductive connection, 123, terminals 124 and 125 and non-piezoelectric layers 130 and 140.

The via 123 may electrically connect the internal electrodes 120 that are arranged side by side. The via 123 may be formed by penetrating the plurality of piezoelectric layers 110. The via 123 may be classified into a via for connecting the first electrodes 121 and a via for connecting the second electrodes 122.

By using the via 123, the plurality of first electrodes 121 and the plurality of second electrodes 122 that are formed on different layers from one another may be readily connected electrically.

The terminals 124 and 125 allow the internal electrodes 120 to be electrically connected with an external power source and may be formed on a surface of the piezoelectric material to be exposed. Meanwhile, in the case where the non-piezoelectric layers 130 and 140 are laminated on the piezoelectric material, the terminals 124 and 125 may be formed on a surface of the non-piezoelectric material.

The terminals 124 and 125 may include a first terminal 124, which is electrically connected with the first electrode 121, and a second terminal 125, which is electrically connected with the second electrode 122.

As shown in FIG. 7, the terminals 124 and 125 may be formed to be in direct contact with the via 123 or in direct contact with the internal electrodes 120. Moreover, the terminals 124 and 125 may be formed to be adjacent to each other.

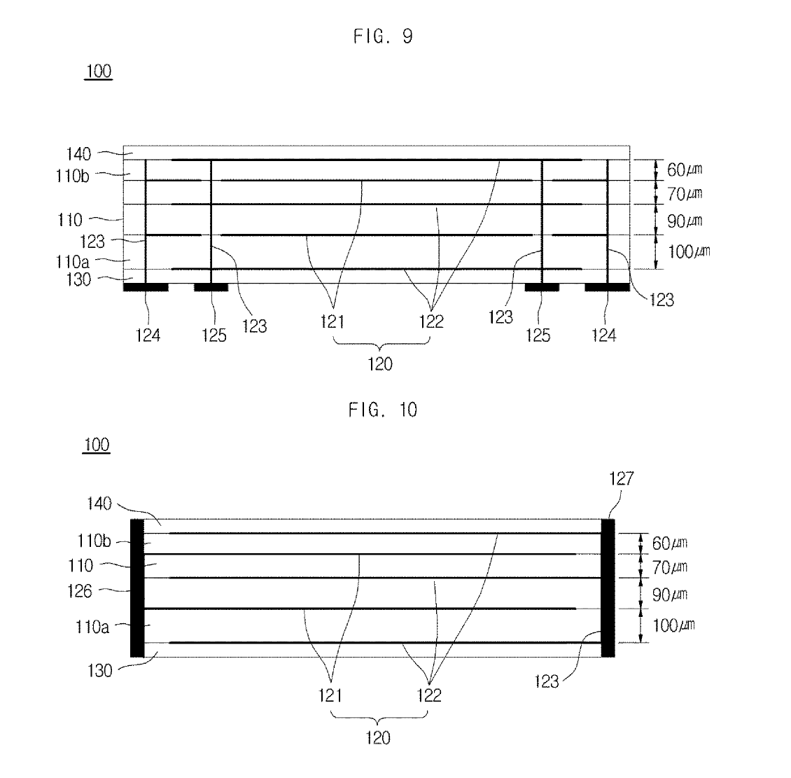

FIG. 9 shows a piezoelectric element in accordance with an embodiment of the present disclosure. As shown in FIG. 9, first terminals 124 and second terminals 125 may each be provided as a pair. That is, there may be four terminals in total. Accordingly, there may be four vias 123 in total as well.

In such a case, the pair of first terminals 124 may be located at either end portion on a piezoelectric material, and the pair of second terminals 125 may also be located at either end portion of the piezoelectric material. In the case where there are four terminals, there may be various ways of connecting power.

FIG. 10 shows a piezoelectric element in accordance with an embodiment of the present disclosure. Referring to FIG. 10, a piezoelectric element 100 in accordance with the present embodiment may include a via 123 and external electrodes that substitute for the terminals 124 and 125 described above.

The external electrodes 126 and 127 are formed on either lateral surface of a piezoelectric material to be electrically connected with internal electrodes 120. The external electrodes 126 and 127 may be configured with an external electrode 126 that is connected with a first electrode and an external electrode 127 that is connected with a second electrode.

In the case where the piezoelectric element 100 includes the external electrodes 126 and 127, a location of a substrate 170, which will be described later, may be changed so that the substrate 170 may be connected with the external electrodes 126 and 127.

The non-piezoelectric layer, which is formed on at least one of a piezoelectric layer 110a located at one end and a piezoelectric layer 110b located at the other end, protects a piezoelectric layer 110 and internal electrodes 120. Because no electric field is formed, the non-piezoelectric layer does not have a piezoelectric property.

The non-piezoelectric layer may include a first cover layer 130 and a second cover layer 140.

The first cover layer 130 is laminated on the piezoelectric layer 110a located at the one end to cover and protect an exposed electrode. That is, the first cover layer 130 protects the electrode that is located at the one end, among the internal electrodes 120. The first cover layer 130 may have the thickness of approximately 30 μm.

The first cover layer 130 may be made of a same material as the piezoelectric layer 110. That is, the first cover layer 130 may include the PNN-PZT ceramic material that is the same for the piezoelectric layer 110. In such a case, the first cover layer 130 may be made of composition having the following formula as a main component.

x[Pb{Zr_{y}Ti_{(1-y)}}O₃]-(1−x)[Pb(Ni_{z}Nb_{(1-z)}O₃]

Here, like the piezoelectric layer 110, x, y, and z may be constants 0.8, 0.44, and ⅓, respectively.

The second cover layer 140 is formed on the piezoelectric layer 110b located at the other end to protect the electrode that is located at the other end, among the internal electrodes 120.

In the piezoelectric vibration module 10, the second cover layer 140 is laminated between the piezoelectric layer 110b located at the other end and the vibrating plate 11. Moreover, the adhesive material 12 is interposed between the second cover layer 140 and the vibrating plate 11. The second cover layer 140 may be formed with a same thickness and a same material as those of the first cover layer 130.

Referring to FIG. 2, the piezoelectric vibration module 10 may further include a weight 150, a first damper 151, a second damper 152, a case 160, and a substrate 170.

The weight 150 is a medium for maximizing the vibrations and is placed over the vibrating plate 11. The haptic functionality may be improved by the weight 150.

The weight 150 may be coupled with the upper-portion plates of the vibrating plate 11 and may be sloped toward a middle portion thereof from end portions thereof in such a way that the weight 150 is not in direct contact with the lower-portion plate. Moreover, the weight 150 may be made of a metallic material, such as tungsten (W), for example, which has a relatively high density.

The case 160, which is a housing that covers the vibrating plate 11, the piezoelectric element 100, and the weight 150, is configured to protect the vibrating plate 11, the piezoelectric element 100, and the weight 150, as well as other internal components of the piezoelectric vibration module 10.

The case 160 may be constituted with an upper-portion case and a lower-portion case. As shown in FIG. 1, the lower-portion case is formed in a long, thin, and flat shape, with a sufficient size to close an open lower face of the upper-portion case. The upper-portion case and the lower-portion case may be coupled with each other by various ways known to the skilled persons in the art, such as caulking, welding, or bonding, for example.

The lower-portion case is spaced by a predetermined distance from the lower-portion plate of the vibrating plate 11 throughout the length of the lower-portion case, and the lower-portion plate may be affixed to both ends of the lower-portion case.

The first damper 151 is interposed between the weight 150 and the case 160 and may prevent the weight 150 from being damaged. The first damper 151 may be coupled to a top portion of the weight 150 and made of an elastic material, such as rubber, for example.

The second damper 152 is interposed between the weight 150 and the vibrating plate 11 and may mitigate a shock between the weight 150 and the vibrating plate 11. The second damper 152 may be coupled to a bottom portion of the weight 150 and, like the first damper 151, may be made of an elastic material, such as rubber, for example.

The substrate 170 is a circuit board being coupled to the piezoelectric element 100 in order to supply electric power to the internal electrodes 120 of the piezoelectric element 100. The substrate 170 may be coupled to a bottom portion of the piezoelectric element 100 and may be a flexible Printed Circuit Board (FPCB).

As described above, the piezoelectric element and the piezoelectric vibration module may reduce the stress on one end of the piezoelectric element by relatively reducing the magnitude of applied electric field on the piezoelectric layer at the one end of the piezoelectric element, thereby reducing possible occurrence of a crack.

Although certain embodiments of the present disclosure have been described, it shall be appreciated that a number of permutations and modifications of the present disclosure are possible by those who are ordinarily skilled in the art to which the present disclosure pertains by supplementing, modifying, deleting, and/or adding some elements without departing from the technical ideas of the present disclosure that are disclosed in the claims appended below and that such permutations and modifications are also covered by the scope of the present disclosure.

Although a few embodiments have been shown and described, it would be appreciated by those skilled in the art that changes may be made in these embodiments without departing from the principles and spirit of the disclosure, the scope of which is defined in the claims and their equivalents.

What is claimed is:

1. A piezoelectric element comprising:
a piezoelectric material formed by laminating a plurality of piezoelectric layers; and
a plurality of internal electrodes laminated alternately with the piezoelectric layers,
wherein a magnitude of an applied electric field on a first piezoelectric layer located at one end of the plurality of piezoelectric layers is smaller than a magnitude of an applied electric field on a second piezoelectric layer located at the other end of the plurality of piezoelectric layers.

2. The piezoelectric element of claim 1, wherein the first piezoelectric layer located at the one end is thicker than the second piezoelectric layer located at the other end.

3. The piezoelectric element of claim 2, wherein the first piezoelectric layer located at the one end is the thickest of the plurality of the piezoelectric layers.

4. The piezoelectric element of claim 2, wherein the second piezoelectric layer located at the other end is the thinnest of the plurality of piezoelectric layers.

5. The piezoelectric element of claim 2, wherein the piezoelectric layers become thinner from the one end toward the other end.

6. The piezoelectric element of claim 2, wherein a ratio of thickness between the first piezoelectric layer located at the one end and the second piezoelectric layer located at the other end is greater than or equal to 0.6 and less than or equal to 0.8.

7. The piezoelectric element of claim 2, wherein the piezoelectric material comprises a plurality of grouped layers,
wherein each of the plurality of grouped layers comprises two or more of the piezoelectric layers that have a same thickness and are consecutively laminated, and
wherein, among the plurality of grouped layers, a grouped layer located at one end of the plurality of grouped layers is thicker than a grouped layer located at an other end of the plurality of grouped layers.

8. The piezoelectric element of claim 1, wherein each of the piezoelectric layers comprises a PNN-PZT ceramic.

9. The piezoelectric element of claim 1, further comprising a via penetrating the piezoelectric layers in such a way that the internal electrodes are electrically connected with one another.

10. The piezoelectric element of claim 9, further comprising terminals formed on the piezoelectric material in such a way that the terminals are electrically connected with the internal electrodes and the via and are exposed to an outside of the piezoelectric material.

11. The piezoelectric element of claim 1, further comprising external electrodes formed on lateral surfaces of the piezoelectric material in such a way that the external electrodes are electrically connected with the internal electrodes.

12. The piezoelectric element of claim 1, further comprising a non-piezoelectric layer being laminated on at least one of the piezoelectric layer located at the one end and the piezoelectric layer located at the other end.

13. A piezoelectric vibration module comprising:
a vibrating plate; and
a piezoelectric element coupled to one surface of the vibrating plate and configured to vibrate the vibrating plate by being contracted and expanded according to a supply of voltage,
wherein the piezoelectric element comprises:
a piezoelectric material formed by laminating a plurality of piezoelectric layers; and
a plurality of internal electrodes laminated alternately with the piezoelectric layers,
wherein, among the plurality of piezoelectric layers, a magnitude of an applied electric field on a first piezoelectric layer located at one end that is farther away from the vibrating plate is smaller than a magnitude of an applied electric field on a second piezoelectric layer located at the other end that is closer to the vibrating plate.

14. The piezoelectric vibration module of claim 13, wherein the first piezoelectric layer located at the one end is thicker than the second piezoelectric layer located at the other end.

15. The piezoelectric vibration module of claim 14, wherein the first piezoelectric layer located at the one end is the thickest of the plurality of the piezoelectric layers.

16. The piezoelectric vibration module of claim 14, wherein the second piezoelectric layer located at the other end is the thinnest of the plurality of piezoelectric layers.

17. The piezoelectric vibration module of claim 14, wherein the piezoelectric layers become thinner from the one end toward the other end.

18. The piezoelectric vibration module of claim 14, wherein a ratio of thickness between the first piezoelectric layer located at the one end and the second piezoelectric layer located at the other end is greater than or equal to 0.6 and less than or equal to 0.8.

19. The piezoelectric vibration module of claim 14, wherein the piezoelectric material comprises a plurality of grouped layers,
wherein each of the plurality of grouped layers comprises two or more of the piezoelectric layers that have a same thickness and are consecutively laminated, and
wherein, among the plurality of grouped layers, a grouped layer located at one end is thicker than a grouped layer located at an other end of the plurality of grouped layers.

20. The piezoelectric vibration module of claim 13, wherein each of the plurality of piezoelectric layers comprises a PNN-PZT ceramic.

21. The piezoelectric vibration module of claim 13, wherein the piezoelectric element further comprises a via penetrating the piezoelectric layers in such a way that the internal electrodes are electrically connected with one another.

22. The piezoelectric vibration module of claim 21, wherein the piezoelectric element further comprises terminals formed on the piezoelectric material in such a way that the terminals are electrically connected with the internal electrodes and the via and are exposed to an outside of the piezoelectric material.

23. The piezoelectric vibration module of claim 13, wherein the piezoelectric element further comprises external electrodes formed on lateral surfaces of the piezoelectric material in such a way that the external electrodes are electrically connected with the internal electrodes.

24. The piezoelectric vibration module of claim 13, wherein the piezoelectric element further comprises a non-piezoelectric layer being laminated on at least one of the first piezoelectric layer located at the one end and the second piezoelectric layer located at the other end.

25. The piezoelectric vibration module of claim 13, further comprising a weight being disposed over the vibrating plate.

26. The piezoelectric vibration module of claim 25, further comprising a case covering the vibrating plate, the piezoelectric element, and the weight.

27. The piezoelectric vibration module of claim 13, further comprising a substrate being coupled to the piezoelectric element in such a way that the voltage is supplied to the piezoelectric element.

28. An apparatus having a vibration function, the apparatus comprising:
a piezoelectric vibration module configured to provide the vibration, the piezoelectric vibration module comprising:
a vibrating plate; and
a piezoelectric element coupled to the vibrating plate and configured to deform when an electric field is applied, the piezoelectric element comprising:
a first piezoelectric layer;
a second piezoelectric layer coupled to the first piezoelectric layer, thinner than the first piezoelectric layer, and closer to the vibrating plate than the first piezoelectric layer; and
a plurality of electrodes configured to apply the electric field to the first piezoelectric layer and the second piezoelectric layer.
